(19) United States
(12) Patent Application Publication
(10) Pub. No.: US 2016/0172528 A1
(43) Pub. Date: Jun. 16, 2016

(54) LIGHT RECEIVING/EMITTING ELEMENT AND SENSOR DEVICE USING SAME

(71) Applicant: KYOCERA CORPORATION, Kyoto (JP)

(72) Inventor: Hiroyuki OKUSHIBA, Kyoto-shi (JP)

(73) Assignee: KYOCERA Corporation, Kyoto-shi, Kyoto (JP)

(21) Appl. No.: 14/907,874

(22) PCT Filed: Jul. 29, 2014
(86) PCT No.: PCT/JP2014/069934

§ 371 Date: Jan. 27, 2016

(30) Foreign Application Priority Data
Jul. 29, 2013 (JP) 2013-156272

(51) Int. Cl. H01L 31/12; H01L 33/58

(52) U.S. Cl. CPC H01L 31/125; H01L 33/58

(57) ABSTRACT

A light receiving/emitting element includes a substrate, a plurality of light emitting elements on or in a first surface of the substrate, and a first light receiving element that is a photodiode at the first surface side of the substrate. The plurality of light emitting elements are arranged in a first direction and constitute a light emitting element array, and the first light receiving element is arranged at the one end side of the light emitting element array. The substrate and the plurality of light emitting elements are formed integrally with each other, and the substrate and the first light receiving element are formed integrally with each other. With those features, a light receiving/emitting element and a sensor device can be realized which are small in size, and which have high sensing performance and high response speed.

### TECHNICAL FIELD

The present invention relates to a light receiving/emitting element that includes a light receiving element and a light emitting element on the same substrate, and further relates to a sensor device using the light receiving/emitting element.

### BACKGROUND ART

Various sensor devices have been proposed so far in relation to the type in which light is applied to an irradiation target from a light emitting element and characteristics of the irradiation target are detected by receiving light, which is reflected by the irradiation target upon incidence of the applied light to it, with a light receiving element. Those sensor devices are utilized in a wide field and are used in a variety of applications including, e.g., a photo-interrupter, a photo-coupler, a remote control unit, an IrDA (Infrared Data Association) communication device, an optical fiber communication device, and a document size sensor.

As one example of those sensor devices, Japanese Unexamined Patent Application Publication No. 2006-226853 discloses a sensor device that measures a distance to an irradiation target by applying light to the irradiation target from a light emitting element, receiving the light regularly reflected by the irradiation target with a light receiving element, such as a PSD (Position Sensitive Detector) or a CCD (Charge Coupled Device), and detecting a spot position of the incident light in a light receiving surface or a barycentric position of light quantity distribution of the incident light in the light receiving surface.

In the above-mentioned type of sensor device, however, because the light receiving element and the light emitting element are independent of each other, problems arise in that productivity is poor due to the necessity of accurate position adjustment in assembly of the sensor device, and that accurate distance measurement cannot be performed unless the position adjustment is accurately finished.

### SUMMARY OF INVENTION

### Technical Problem

In consideration of the problems mentioned above, an object of the present invention is to provide a light receiving/emitting element with high sensing performance, and a sensor device using the light receiving/emitting element.

### Solution to Problem

The present invention provides a light receiving/emitting element including a substrate, a plurality of light emitting elements, and a first light receiving element. The plurality of light emitting elements are arranged in a first direction and constitute a light emitting element array. The first light receiving element is a photodiode in or on a first surface of the substrate. The first light receiving element is arranged at a one end side of the light emitting element array. The substrate and the plurality of light emitting elements are formed integrally with each other. Similarly, the substrate and the first light receiving element are formed integrally with each other.

The present invention provides a sensor device using the above-described light receiving/emitting element according to the present invention, wherein lights are sequentially applied from the plurality of light emitting elements to an irradiation target, and distance information of the irradiation target is detected on the basis of position information of each of the light emitting elements having emitted the lights applied to the irradiation target, and output currents that are output from the first light receiving element corresponding to reflected lights from the irradiation target.

The present invention further provides a sensor device using the light receiving/emitting element according to the present invention. The light receiving/emitting element further includes a second light receiving element that is disposed corresponding to the plurality of light emitting elements, and that includes a second opposite conductivity type semiconductor region formed in the first surface of the substrate and containing an impurity having an opposite conductivity type, the second light receiving element being arranged along the light emitting element array. In the sensor device, lights are sequentially applied from the plurality of light emitting elements to an irradiation target, and position information and distance information of the irradiation target are detected on the basis of position information of each of the light emitting elements having emitted the lights applied to the irradiation target, and output currents that are output from the first light receiving element and the second light receiving element corresponding to reflected lights from the irradiation target.

### BRIEF DESCRIPTION OF DRAWINGS

FIG. 1 is a plan view illustrating an exemplary embodiment of a light receiving/emitting element according to the present invention.

FIG. 2(a) is a sectional view of a light emitting element constituting the light receiving/emitting element illustrated in FIG. 1. FIG. 2(b) is a sectional view of a light receiving element constituting the light receiving/emitting element illustrated in FIG. 1.

FIG. 3 is a schematic sectional view illustrating an exemplary embodiment of a sensor device using the light receiving/emitting element illustrated in FIG. 1.

FIG. 4 is a schematic sectional view illustrating a first modification of the light receiving/emitting element illustrated in FIG. 1.

FIG. 5 is a schematic sectional view illustrating a second modification of the light receiving/emitting element illustrated in FIG. 1.

FIG. 6 is a plan view illustrating a third modification of the light receiving/emitting element illustrated in FIG. 1.

FIG. 7 is a plan view illustrating a fourth modification of the light receiving/emitting element illustrated in FIG. 1.

FIGS. 8(a) and 8(b) are each a schematic sectional view illustrating a fifth modification of the light receiving/emitting element illustrated in FIG. 1.

FIG. 9 is a graph depicting output changes of a first light receiving element when the distance to an irradiation target is changed in a light receiving/emitting element of EXAMPLE.

### DESCRIPTION OF EMBODIMENTS

Exemplary embodiments of a light receiving/emitting element and a sensor device using the light receiving/emitting element, according to the present invention, will be described below with reference to the drawings. It is to be noted that the following description represents embodiments of the present invention by way of example, and that the present invention is not limited to the embodiments described below.

(Light Receiving/Emitting Element)

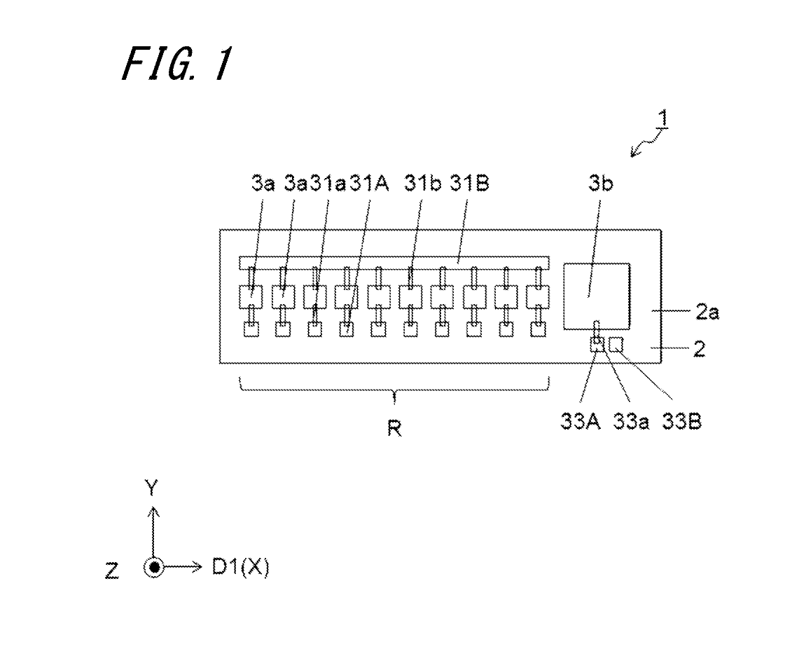

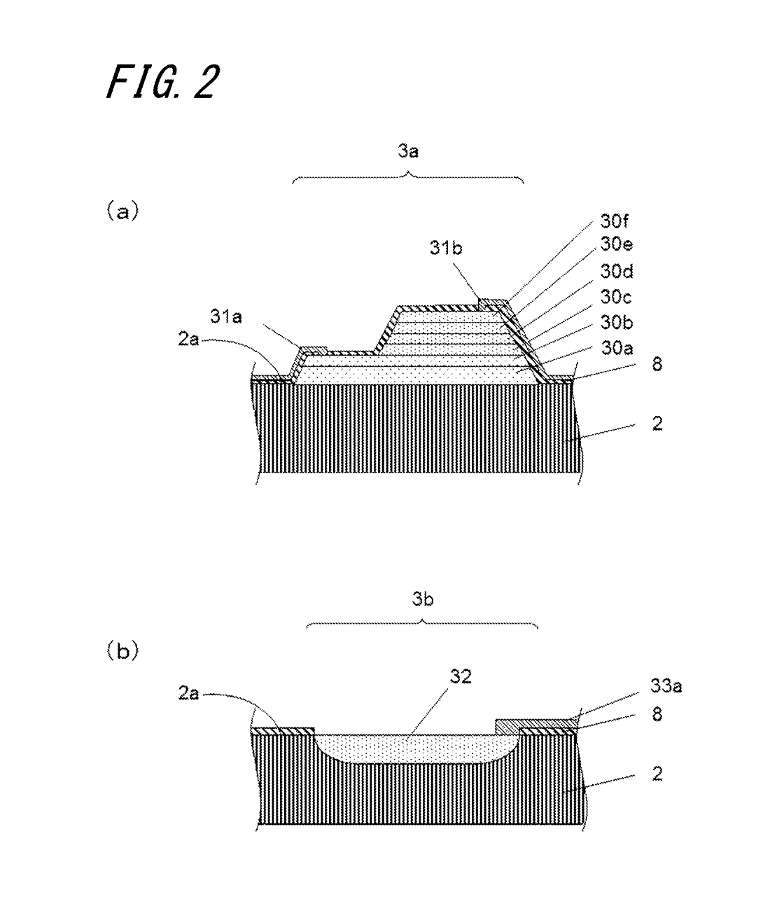

A light receiving/emitting element 1 illustrated in FIGS. 1 and 2 is assembled into an image forming apparatus, such as a copying machine or a printer, and it functions as a sensor device for detecting distance information of an irradiation target, such as toner or a medium.

The light receiving/emitting element 1 includes a substrate 2, a plurality of light emitting elements 3a on a first surface 2a of the substrate 2, and a first light receiving element 3b in the first surface 2a. The first light receiving element 3b is a photodiode including a first opposite conductivity type semiconductor region 32 that contains an impurity having an opposite conductivity type. The substrate 2 and the plurality of light emitting elements 3a are formed integrally with each other. Similarly, the substrate 2 and the first light receiving element 3b are formed integrally with each other. In other words, the plurality of light emitting elements 3a and the first light receiving element 3b are fabricated on and in the same substrate 2 in an integral form.

In the embodiment illustrated in FIGS. 1 and 2, a semiconductor material having one conductivity type is used as the substrate 2. Each of the light emitting elements 3a includes a plurality of semiconductor layers laminated on the first surface 2a of the substrate 2, and the first light receiving element 3b includes, in the first surface 2a of the substrate 2, the first opposite conductivity type semiconductor region 32 where the impurity having the opposite conductivity type is doped. The first light receiving element 3b constituting a photodiode by forming a pn junction between the first opposite conductivity type semiconductor region 32, which is fabricated in a portion continuously extending inwards from the first surface 2a of the substrate 2, and a one conductivity type region of the substrate 2, the one conductivity type region being adjacent to the first opposite conductivity type semiconductor region 32. Thus, the substrate 1, the light emitting elements 3a, the first light receiving element 3b can be fabricated in the form of a single substrate.

It is just required that the light emitting elements 3a and the first light receiving element 3b are formed integrally with the substrate 2 and are arranged at the side including the first surface 2a. In other words, those components may be all disposed on the first surface 2a of the substrate 2, or part or all of the components may be fabricated inside the substrate 2. In the latter case, at least light emitting surfaces of the light emitting elements 3a and a light receiving surface of the first light receiving element 3b are held in a state exposed to the first surface 2a.

The substrate 2 is made of a semiconductor material having the one conductivity type. There is no limitation on concentration of an impurity having the one conductivity type. In this embodiment, an n-type Si substrate containing, as the impurity having the one conductivity type, phosphorus (P) at a concentration of 1×10¹⁷ to 2×10¹⁷ atoms/cm³ in a silicon (Si) substrate is used as the substrate 2. Examples of the n-type impurity include, in addition to P, nitrogen (N), arsenic (As), antimony (Sb), and bismuth (Bi). A doping concentration is set to 1×10¹⁶ to 1×10²⁰ atoms/cm³.

The substrate 2 has a crystal structure allowing semiconductor layers, which constitute the light emitting element 3a described later, to be grown on the first surface 2a of the substrate 2.

In this embodiment, the one conductivity type is an n-type, and the opposite conductivity type is a p-type.

On the upper surface of the substrate 2, the plurality of light emitting elements 3a are arranged in a first direction (i.e., a direction D1 in FIG. 1) and constitute a light emitting element array R. The first light receiving element 3b is arranged at the one end side of the light emitting element array R. The plurality of light emitting elements 3a function as light sources each emitting light applied to an irradiation target. The light emitted from the light emitting element 3a is reflected by the irradiation target and is incident on the first light receiving element 3b. The first light receiving element 3b functions as an optical detector for detecting the incidence of light. Thus, the light emitting surface of the light emitting element 3a and the first receiving surface of the first light receiving element 3b are parallel to the first surface 2a of the substrate 2.

In this embodiment, the first light receiving element 3b is arranged in line with the plurality of light emitting elements 3a. However, both the elements are not always required to be arranged in line, and the first light receiving element 3b is just required to be arranged at the one end side of the light emitting element array R within a range where the triangulation method can be applied. Here, the term “one end side” means a region around a center, as a reference, of the light emitting element 3a that is positioned at an end of the light emitting element array R in the first direction along which the plurality of light emitting elements 3a are arranged, the region extending outwards of the light emitting element array R in the first direction.

The light emitting elements 3a are each formed, as illustrated in FIG. 2(a), by laminating a plurality of semiconductor layers on the first surface 2a of the substrate 2 that is made of the n-type semiconductor material.

First, a buffer layer 30a for buffering a difference in lattice constant between the substrate 2, which is made of the n-type semiconductor material, and a semiconductor layer (later-described n-type contact layer 30b in this embodiment), which is laminated on the upper surface of the substrate 2, is formed on the first surface 2a of the n-type substrate 2. With the buffer layer 30a buffering the difference in lattice constant between the substrate 2 and the semiconductor layer formed on the first surface 2a of the substrate 2, lattice defects, such as lattice distortion, generated at the interface between the substrate 2 and the semiconductor layer constituting the light emitting element 3a are reduced. Thus, the buffer layer 30a has the function of reducing the lattice defects or crystal defects in the entire semiconductor layer, which is formed on the first surface 2a of the substrate 2 and which constitutes the light emitting element 3a.

The buffer layer 30a in this embodiment is made of gallium arsenic (GaAs) containing no impurities and it has a thickness of about 2 to 3 μm. When the difference in lattice constant between the substrate 2 and the semiconductor layer, which is formed on the first surface 2a of the n-type substrate 2 and which constitutes the light emitting element 3a, is not large, the buffer layer 30a may be omitted.

An n-type contact layer 30b is formed on an upper surface of the buffer layer 30a. The n-type contact layer 30b is made of GaAs doped with, e.g., Si or selenium (Se) as an n-type impurity. A doping concentration in the n-type contact layer 30b is about 1×10¹⁶ to 1×10²⁰ atoms/cm³, and a thickness of the n-type contact layer 30b is about 0.8 to 1 μm.

In this embodiment, Si is doped as the n-type impurity in the n-type contact layer 30b at a doping concentration of 1×10¹⁸ to 2×10¹⁸ atoms/cm³. A portion of an upper surface of the n-type contact layer 30b is exposed, and the exposed portion is connected to a first electrode pad 31A on the light emitting element side through a first electrode 31a on the light emitting element side. In this embodiment, though not illustrated, the first electrode pad 31A on the light emitting element side and an external power supply are connected to each other by wire bonding using a gold (Au) wire. As a matter of course, another type of wire, e.g., an aluminum (Al) wire or a copper (Cu) wire may also be used instead of the Au wire.

While, in this embodiment, the first electrode pad 31A on the light emitting element side and the external power supply are connected to each other by wire bonding, other bonding methods than the wire bonding may also be used. For example, an electrical wiring line may be joined to the first electrode pad 31A on the light emitting element side by soldering.

Alternatively, a gold (Au) stud bump may be formed on an upper surface of the first electrode pad 31A on the light emitting element side, and an electrical wiring line may be joined to the gold stud bump by soldering.

The n-type contact layer 30b has the function of reducing contact resistance with respect to the first electrode 31a on the light emitting element side, which is connected to the n-type contact layer 30b.

The first electrode 31a on the light emitting element side and the first electrode pad 31A on the light emitting element side are each formed in a thickness of about 0.5 to 5 μm by employing, e.g., a gold (Au)-antimony (Sb) alloy, a gold (Au)-germanium (Ge) alloy, or a Ni-based alloy. In addition, because the first electrode 31a on the light emitting element side and the first electrode pad 31A on the light emitting element side are disposed on an insulating layer 8 that covers the upper surface of the semiconductor substrate 2 and the upper surface of the n-type contact layer 30b in a continuously extending state, the first electrode 31a and the first electrode pad 31A are electrically insulated from the other semiconductor layers than the semiconductor substrate 2 and the n-type contact layer 30b, respectively.

The insulating layer 8 is formed of, for example, an inorganic insulating film made of, e.g., silicon nitride (SiNₓ) or silicon oxide (SiO₂), or an organic insulating film made of, e.g., polyimide. The insulating layer 8 has a thickness of about 0.1 to 1 μm.

An n-type cladding layer 30c is formed on the upper surface of the n-type contact layer 30b, and it has the function of enclosing holes in a later-described active layer 30d. The n-type cladding layer 30c is made of aluminum gallium arsenic (AlGaAs) doped with, e.g., Si or selenium (Se) as an n-type impurity. The n-type cladding layer 30c has a doping concentration of about 1×10¹⁶ to 1×10²⁰ atoms/cm³, and a thickness of about 0.2 to 0.5 μm. In this embodiment, Si is doped as the n-type impurity at a doping concentration of 1×10¹⁷ to 5×10¹⁷ atoms/cm³.

The active layer 30d is formed on an upper surface of the n-type cladding layer 30c. The active layer 30d functions as a light emitting layer in which carries, such as electrons and holes, are concentrated and light is generated upon recombination of those carries. The active layer 30d is made of AlGaAs containing no impurities, and it has a thickness of about 0.1 to 0.5 μm. While the active layer 30d in this embodiment is a layer containing no impurities, the active layer 30d may be a p-type active layer containing a p-type impurity, or an n-type active layer containing an n-type impurity insofar as a bandgap of the active layer is smaller than that of the n-type cladding layer 30c or a p-type cladding layer 30e described below.

The p-type cladding layer 30e is formed on an upper surface of the active layer 30d, and it has the function of enclosing electrons in the active layer 30d. The p-type cladding layer 30e is made of AlGaAs doped with, e.g., zinc (Zn), magnesium (Mg) or carbon (C) as a p-type impurity. A doping concentration in the p-type cladding layer 30e is about 1×10¹⁶ to 1×10²⁰ atoms/cm³, and a thickness of the p-type cladding layer 30e is about 0.2 to 0.5 μm. In this embodiment, Mg is doped as the p-type impurity at a doping concentration of 1×10¹⁹ to 5×10²⁰ atoms/cm³.

A p-type contact layer 30f is formed on an upper surface of the p-type cladding layer 30e. The p-type contact layer 30f is made of AlGaAs doped with, e.g., Zn, Mg or C as a p-type impurity. A doping concentration in the p-type contact layer 30f is about 1×10¹⁶ to 1×10²⁰ atoms/cm³, and a thickness of the p-type contact layer 30f is about 0.2 to 0.5 μm.

The p-type contact layer 30f is connected to a second electrode pad 31B on the light emitting element side through a second electrode 31b on the light emitting element side. As in the case of the first electrode pad 31A on the light emitting element side, the second electrode pad 31B on the light emitting element side is electrically connected to the external power supply by wire bonding. Variations of the connecting method and the joined form are similar to those in the case of the first electrode pad 31A on the light emitting element side. The p-type contact layer 30f has the function of reducing contact resistance with respect to the second electrode 31b on the light emitting element side, which is connected to the p-type contact layer 30f. In this embodiment, the second electrode pad 31B on the light emitting element side is connected in common to the plurality of light emitting elements 3a.

A cap layer with the function of preventing oxidation of the p-type contact layer 30f may be formed on an upper surface of the p-type contact layer 30f. The cap layer may be made of, e.g., GaAs containing no impurities, and may have a thickness of about 0.01 to 0.03 μm.

The second electrode 31b on the light emitting element side and the second electrode pad 31B on the light emitting element side are each formed in a thickness of about 0.5 to 5 μm by employing, e.g., an AuNi, AuCr, AuTi, or AlCr alloy in combination of Au or Al and nickel (Ni), chromium (Cr), or titanium (Ti), the latter forming an adhesive layer. In addition, because the second electrode 31b on the light emitting element side and the second electrode pad 31B on the light emitting element side are disposed on the insulating layer 8 that covers the upper surface of the substrate 2 and the upper surface of the p-type contact layer 30f in a continuously extending state, the second electrode 31b and the second electrode pad 31B are electrically insulated from the other semiconductor layers than the substrate 2 and the p-type contact layer 30f, respectively.

The light emitting element 3a constituted as described above functions as a light source with the active layer 30d generating light upon application of a bias between the first electrode pad 31A on the light emitting element side and the second electrode pad 31B on the light emitting element side.

The first light receiving element 3b is constituted, as illustrated in FIG. 2(b), by forming the first opposite conductivity type semiconductor region 32 (hereinafter referred to also as a “p-type semiconductor region 32”) in the first surface 2a of the substrate 2 made of the n-type semiconductor material, thereby forming a pn junction in cooperation with the n-type substrate 2. The p-type semiconductor region 32 is formed by diffusing a p-type impurity into the n-type substrate 2 at a high concentration. The p-type impurity is, for example, Zn, Mg, C, B, In, or Se. A doping concentration is set to 1×10¹⁶ to 1×10²⁰ atoms/cm³. In this embodiment, B is diffused as the p-type impurity such that the p-type semiconductor region 32 has a thickness of about 0.5 to 3 μm.

The p-type semiconductor region 32 is electrically connected to a first electrode pad 33A on the first light receiving element side through a first electrode 33a on the first light receiving element side, and a second electrode pad 33B on the first light receiving element side is electrically connected to the n-type substrate 2.

Because the first electrode 33a on the first light receiving element side and the first electrode pad 33A on the first light receiving element side are disposed on the upper surface of the n-type substrate 2 with the insulating layer 8 interposed therebetween, the first electrode 33a and the first electrode pad 33A are electrically insulated from the substrate 2. On the other hand, the second electrode pad 33B on the first light receiving element side is disposed on the upper surface of the substrate 2.

The first electrode 33a on the first light receiving element side, the first electrode pad 33A on the first light receiving element side, and the second electrode pad 33B on the first light receiving element side are each formed in a thickness of about 0.5 to 5 μm by employing, e.g., an AuSb alloy, an AuGe alloy, or a Ni-based alloy.

The first light receiving element 3b constituted as described above generates a photocurrent with the photovoltaic effect upon incidence of light on the p-type semiconductor region 32, and functions as an optical detector from which the generated photocurrent is taken out through the first electrode pad 33A on the first light receiving element side. Preferably, a reverse bias is applied between the first electrode pad 33A on the first light receiving element side and the second electrode pad 33B on the first light receiving element side from the viewpoint of increasing photo-detection sensitivity of the first light receiving element 3b.

The reason why the light receiving/emitting element 1 according to this embodiment functions as a sensor device for detecting distance information of the irradiation target is described here.

The plurality of light emitting elements 3a in this embodiment constitute the light emitting element array R in which the light emitting elements 3a are arranged on a line extending in the first direction. The plurality of light emitting elements 3a are operated under control of an external control circuit and sequentially emit lights. For example, the plurality of light emitting elements 3a sequentially emit lights in order starting from one of the light emitting elements 3a, which is positioned closest to the first light receiving element 3b, toward the side away from the first light receiving element 3b.

The light emitted from each light emitting element 3a is reflected by the irradiation target, and the reflected light is incident or not incident on the first light receiving element 3b depending on the distance of the irradiation target from the light receiving/emitting element 1. Accordingly, distance information between the light receiving/emitting element 1 and the irradiation target can be detected in accordance with the triangulation method.

Furthermore, even when the reflected light is incident on the first light receiving element 3b, a value of the photocurrent generated with the photovoltaic effect is different depending on the distance of the irradiation target from the light receiving/emitting element 1. Accordingly, the distance information between the light receiving/emitting element 1 and the irradiation target can be detected with higher accuracy by previously forming a database, which represents relations between values of photocurrents, detected by the first light receiving element 3b when the plurality of light emitting elements 3a sequentially emit lights, and the distance to the irradiation target, storing the database in an external storage device, and by employing an external comparison circuit that refers to the stored database.

According to the light receiving/emitting element 1, as described above, the light emitting elements 3a and the first light receiving element 3b are fabricated integrally with the single substrate 2. Therefore, the light emitting elements 3a and the first light receiving element 3b can be arranged in the desired positional relation with high position accuracy. Thus, since accurate position adjustment is ensured in the light receiving/emitting element 1, accurate distance measurement can be realized, and hence high sensing performance can be obtained.

Furthermore, the light receiving/emitting element 1 does not need a lens having a size as large as that of the lens used in the related art utilizing a PSD or a CCD. Stated in another way, since the light emitting element 3a has higher directivity than an LED of bombshell type mounted to the substrate 2, a lens is not necessarily required. Even when a lens is used, a smaller lens is used to be adapted for each of the light emitting elements 3a and the first light receiving element 3b. Accordingly, the light receiving/emitting element 1 having a smaller size can be provided.

According to the light receiving/emitting element 1, since the photodiode having a higher response speed than the PSD or the CCD is used, the measurement can be completed in a shorter time.

In comparison with the case where a light receiving/emitting element is constituted by a plurality of light receiving elements arrayed in one direction and one light emitting element disposed at the one end side of an array of the light receiving elements, the light receiving/emitting element 1 can be obtained in a smaller size with a simplified structure. Moreover, according to the light receiving/emitting element 1, since the plurality of light emitting elements 3a are sequentially turned on, generation of heat from each light emitting element 3a can be suppressed, and the lifetime of each element can be prolonged. In addition, operations for driving and controlling the light emitting elements 3a are facilitated.

Since the first light receiving element 3b made of the Si-based material is fabricated in the same substrate in match with the wavelength of the light emitted from the light emitting element 3a made of the GaAs-based material, the light receiving/emitting element 1 having high sensitivity can be obtained.

(Manufacturing Method for Light Receiving/Emitting Element)

An example of a manufacturing method for the light receiving/emitting element 1 will be described below.

First, an n-type Si substrate doped with P as an n-type impurity is prepared as the substrate 2 made of the n-type semiconductor material. An impurity concentration of P in this example is 1×10¹⁷ to 2×10¹⁷ atoms/cm³. Examples of the n-type impurity include nitrogen N, As, Sb and Bi in addition to P. A doping concentration is set to 1×10¹⁶ to 1×10²⁰ atoms/cm³.

Next, a diffusion blocking film S (not illustrated) made of silicon oxide (SiO₂) is formed on the substrate 2 by the ordinary thermal oxidation method.

A photoresist is coated over the diffusion blocking film S, and a desired pattern is formed in the photoresist through exposure and development by the ordinary photolithographic method. Thereafter, an opening Sa (not illustrated) in which the p-type semiconductor region 32 is to be formed is formed in the diffusion blocking film S by the ordinary wet etching method. The opening Sa is not always required to penetrate through the diffusion blocking film S.

A poly boron film (PBF) is then coated over the diffusion blocking film S. Subsequently, the p-type semiconductor region 32 is formed by diffusing B, which is contained in the PBF, into the substrate 2 through the opening Sa of the diffusion blocking film S with the thermal diffusion method. At that time, for example, a thickness of the PBF is set to 0.1 to 1 μm, and the thermal diffusion is carried out at temperature of 700 to 1200° C. in an atmosphere containing nitrogen (N₂) and oxygen (O₂). Thereafter, the diffusion blocking film S is removed.

Next, an oxide film having been naturally formed on the surface of the substrate 2 is removed by heat-treating the substrate 2 in a reaction furnace of an MOCVD (Meta-organic Chemical Vapor Deposition) apparatus. The heat treatment is carried out, for example, at temperature of 1000° C. for about 10 min.

Next, the individual semiconductor layers (i.e., the buffer layer 30a, the n-type contact layer 30b, the n-type cladding layer 30c, the active layer 30d, the p-type cladding layer 30e, and the p-type contact layer 30f), which constitute the plurality of light emitting elements 3a, are successively laminated on the substrate 2 by the MOCVD method. A photoresist is coated over the laminated semiconductor layers L (not illustrated), and desired patterns are formed in the photoresist through exposure and development by the ordinary photolithographic method. Thereafter, the plurality of light emitting elements 3a are formed by the ordinary wet etching method. The etching is performed plural times such that the upper surface of the n-type contact layer 30b is partly exposed. The photoresist is then removed.

Next, the insulating layer 8 is formed by the ordinary thermal oxidation method, sputtering method, or plasma CVD method, for example, in a state covering the exposed surfaces of the light emitting elements 3a and the upper surface of the substrate 2 (including the p-type semiconductor region 32). A photoresist is coated over the insulating layer 8, and a desired pattern is formed in the photoresist through exposure and development by the ordinary photolithographic method. Thereafter, openings through which the first electrodes 31a on the light emitting element side, the second electrodes 31b on the light emitting element side, and the first electrode 33a on the first light receiving element side are connected respectively to the n-type contact layer 30b, the p-type contact layer 30f, and the p-type semiconductor region 32, as described later, are formed in the insulating layer 8 by the ordinary wet etching method. The photoresist is then removed.

Next, a photoresist is coated over the insulating layer 8, and a desired pattern is formed in the photoresist through exposure and development by the ordinary photolithographic method. Thereafter, alloy films to form the first electrodes 31a on the light emitting element side, the first electrode pads 31A on the light emitting element side, the first electrode 33a on the first light receiving element side, the first electrode pad 33A on the first light receiving element side, and the second electrode pad 33B on the first light receiving element side are formed by the ordinary resistance heating method or sputtering method, for example. Then, by employing the ordinary liftoff method, the photoresist is removed such that the first electrodes 31a on the light emitting element side, the first electrode pads 31A on the light emitting element side, the first electrode 33a on the first light receiving element side, the first electrode pad 33A on the first light receiving element side, and the second electrode pad 33B on the first light receiving element side are formed in the desired shapes. The second electrode 31b on the light emitting element side and the second electrode pad 31B on the light emitting element side are also formed in a similar manner to that described above.

As a result, the light receiving/emitting element 1 can be manufactured. The light emitting elements 3a and the first light receiving element 3b can be fabricated in the same substrate 2. Since position accuracy in arrangement of those elements is determined depending on patterning accuracy, higher position accuracy can be realized in comparison with the case of separately mounting individual components.

Furthermore, since the plurality of light emitting elements 3a are formed on the same substrate 2 through the same processes, variations of characteristics generated among the plurality of light emitting elements 3a can be suppressed.

While the above example has been described in connection with the case of forming the first opposite conductivity type semiconductor region 32 by thermal diffusion, the first opposite conductivity type semiconductor region 32 may be formed by ion implantation. Moreover, while the light emitting element 3a is formed by laminating the semiconductor layers on the substrate 2, the light emitting element 3a may be formed by bonding epitaxial films, which have respective desired characteristics, into the form of multilayered films. Similarly, the first light receiving element 3b may also be formed by bonding epitaxial films into the form of multilayered films.

(Sensor Device)

A sensor device 100 including the light receiving/emitting element 1 will be described below. The following description is made, by way of example, in connection with the case where the light receiving/emitting element 1 is applied to a sensor device for detecting a distance to a recording medium T (irradiation target) in an image forming apparatus, such as a copying machine or a printer.

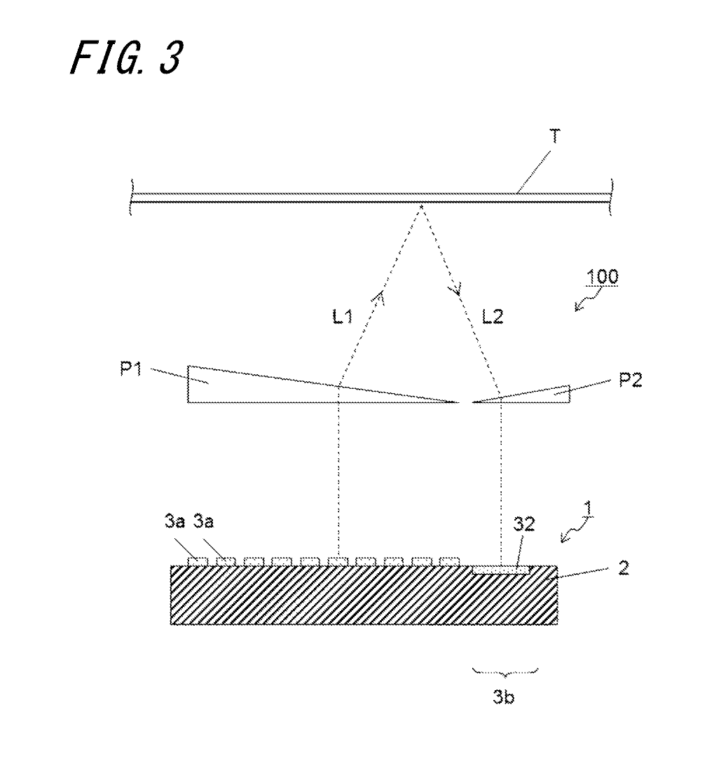

As illustrated in FIG. 3, the sensor device 100 according to the exemplary embodiment is arranged such that the surface of the light receiving/emitting element 1 on which the plurality of light emitting elements 3a and the first light receiving element 3b are formed is directed toward the recording medium T. Lights are sequentially applied from the plurality of light emitting elements 3a to the recording medium T that is the irradiation target. In this embodiment, a prism P1 is arranged above the plurality of light emitting elements 3a, and a prism P2 is arranged above the first light receiving element 3b. The light emitted from each light emitting element 3a is refracted through the prism P1 and is incident on the recording medium T. Regularly reflected light L2 corresponding to the incident light L1 is refracted through the prism P2 such that the light emitted from the relevant light emitting element 3a is received by the first light receiving element 3b. In the illustrated case, the light emitted from the light emitting element 3a, which is present at the fifth position counting from the side close to the first light receiving element 3b, is incident on the first light receiving element 3b. A photocurrent is generated in the first light receiving element 3b depending on the intensity of the received light, and the generated photocurrent is detected by an external device through the first electrode 33a on the first light receiving element side, etc. In such a way, distance information of the recording medium T can be detected on the basis of position information of the light emitting element 3a having emitted the light applied to the recording medium T as the irradiation target, and an output current (photocurrent) that is output from the first light receiving element 3b corresponding to the reflected light from the recording medium T.

According to the sensor device 100 of this embodiment, the photocurrent depending on the intensity of the light regularly reflected by the recording medium T can be detected as described above. Therefore, in one example, the distance to the recording medium T can be detected with high accuracy in accordance with a value of the photocurrent detected by the first light receiving element 3b.

According to the sensor device 100 of this embodiment, the above-described advantageous effects of the light receiving/emitting element 1 can also be obtained.

Although the practical exemplary embodiments of the present invention have been described above, the present invention is not limited to the above embodiments, and the present invention can be variously modified within the scope not departing from the gist of the invention.

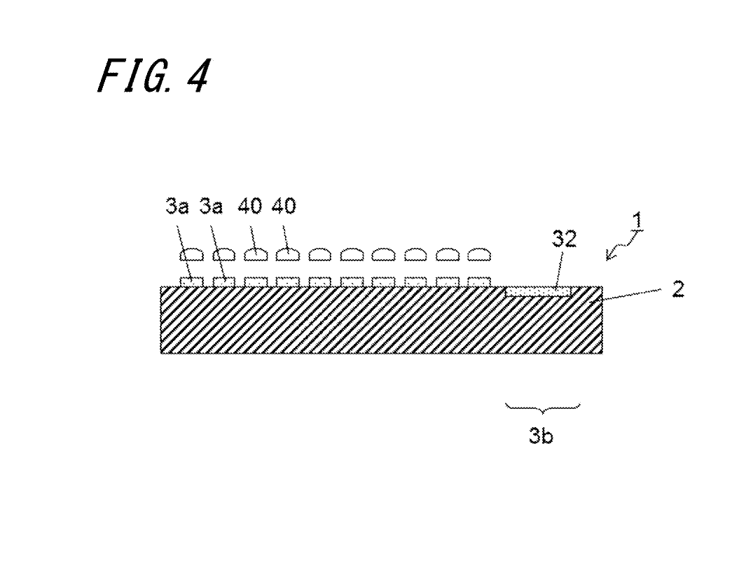

As in a first modification illustrated in FIG. 4, for example, the light receiving/emitting element 1 may further include a plurality of lenses 40 that are disposed corresponding to the plurality of light emitting elements 3a, and that condense the lights emitted from the plurality of light emitting elements 3a, respectively. The plurality of lenses 40 are arranged above the corresponding light emitting elements 3a in the direction of thickness of the substrate 2 (i.e., the direction in which the plurality of semiconductor layers are laminated). With such an arrangement, the lights emitted from the light emitting elements 3a are condensed, and a quantity of light incident on the first light receiving element 3b is increased. Hence detection sensitivity of the first light receiving element 3b is increased.

A plano-convex lens is used as each of the lenses 40 in this modification. Thus, in the lens 40 used in this modification, one principal surface has a convex shape, and the other principal surface has a planar shape. Moreover, a cross-sectional area of the lens 40 is gradually reduced toward the one principal surface from the other principal surface. A material of the lens 40 is optionally selected from not only plastics including thermosetting resins, such as silicone, urethane, and epoxy, and thermoplastic resins, such as polycarbonate and acryl, but also sapphire and inorganic glass. While a plano-convex lens is used as the lens 40 in this embodiment, another type lens, e.g., a biconvex lens may also be used.

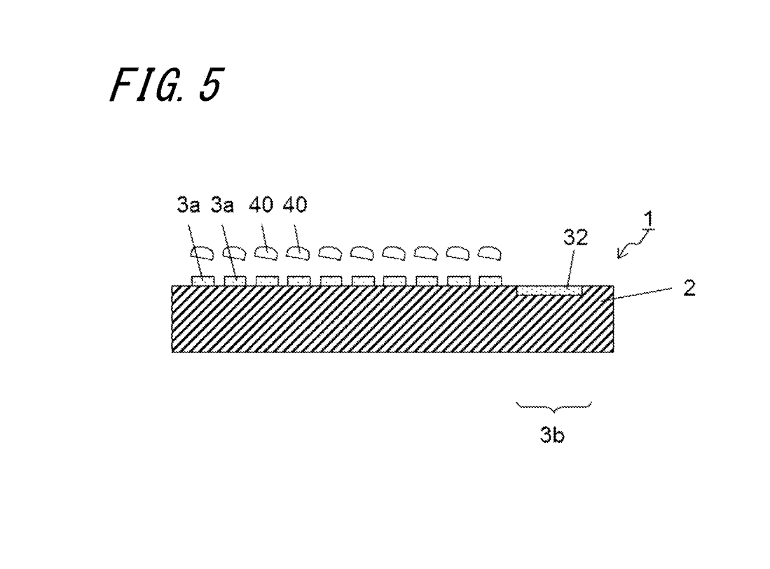

As in a second modification illustrated in FIG. 5, axes of the lights emitted from the plurality of light emitting elements 3a and applied through the plurality of lenses 40, respectively, may be inclined toward the side where the first light receiving element 3b is positioned. In the second modification, the respective axes of the lights emitted from the plurality of light emitting elements 3a are inclined toward the side where the first light receiving element 3b is positioned, by inclining the plurality of lenses 40 from a horizontal direction toward the first light receiving element 3b. Methods for inclining the respective axes of the lights emitted from the plurality of light emitting elements 3a are not limited to the above-described one. As another method, the center of each lens 40 may be displaced to come closer to the first light receiving element 3b than the center of the corresponding light emitting element 3a when the light receiving/emitting element 1 is looked at in a plan view from the side facing the light emitting elements 3a. Here, the “center of the light emitting element 3a” means the center of the active layer 30d that serves as a light emitting layer. However, because the p-type cladding layer 30e, the p-type contact layer 30f and so on are laminated on the active layer 30d, the center of the active layer 30d cannot be directly recognized. Accordingly, the center of the p-type contact layer 30f may be regarded as the center of the active layer 30d for the sake of expedience. The center of the lens 40 means the apex of a convex portion when the lens 40 is a plano-convex lens. As a still another method, the respective axes of the lights emitted from the plurality of light emitting elements 3a may be inclined by displacing the center of each lens 40 to come closer to the first light receiving element 3b than the center of the corresponding light emitting element 3a while the lens 40 is inclined as mentioned above.

In the modifications illustrated in FIGS. 4 and 5, a lens may be disposed corresponding to the first light receiving element 3b.

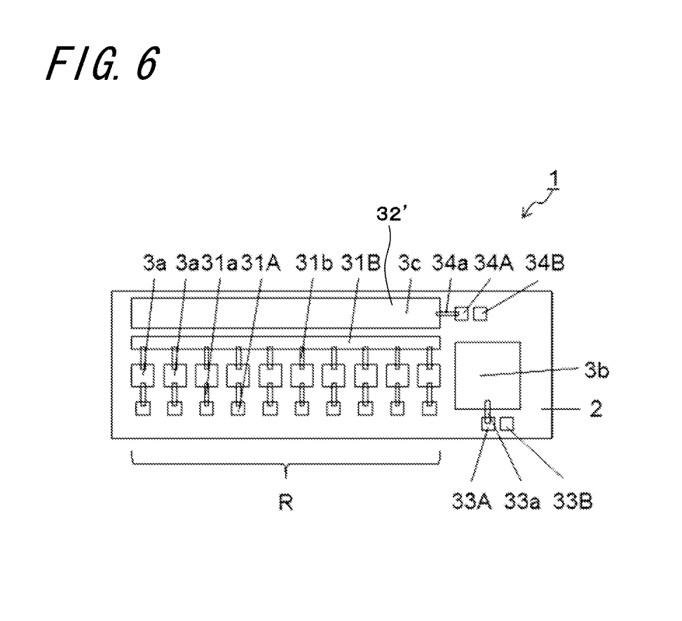

As in a third modification illustrated in FIG. 6, the light receiving/emitting element 1 may further include a second light receiving element 3c that is disposed corresponding to the plurality of light emitting elements 3a, and that has a second opposite conductivity type semiconductor region 32′ formed in the first surface 2a of the substrate 2. The second light receiving element 3c may be arranged along the light emitting element array R. In this modification, a semiconductor material having one conductivity type is used as the substrate 2, and the second opposite conductivity type semiconductor region 32′ is formed by diffusing an impurity having the opposite conductivity type into the substrate 2 from the side including the first surface 2a.

With the arrangement described above, since the plurality of light emitting elements 3a sequentially emit lights under control of an external control circuit and the lights reflected by the irradiation target are sequentially incident on the first light receiving element 3b, distance information of the irradiation target from the light receiving/emitting element 1 can be detected. In addition, since the lights reflected by the irradiation target are sequentially incident on the second light receiving element 3c, position information of the irradiation target in the direction in which the plurality of light emitting elements 3a are arrayed can be further detected.

The second light receiving element 3c in the third modification is constituted by one light receiving element having substantially the same length as that of the light emitting element array R and arranged along the light emitting element array R. The second light receiving element 3c is connected to a first electrode pad 34A on the second light receiving element side through a first electrode 34a on the second light receiving element side. A second electrode pad 34B on the second light receiving element side is further disposed and connected to the substrate 2. The second light receiving element 3c is formed in a similar manner to the first light receiving element 3b. The first electrode 34a on the second light receiving element side is formed in a similar manner to the first electrode 33a on the first light receiving element side. The first electrode pad 34A on the second light receiving element side is formed in a similar manner to the first electrode pad 33A on the first light receiving element side. The second electrode pad 34B on the second light receiving element side is formed in a similar manner to the second electrode pad 33B on the first light receiving element side.

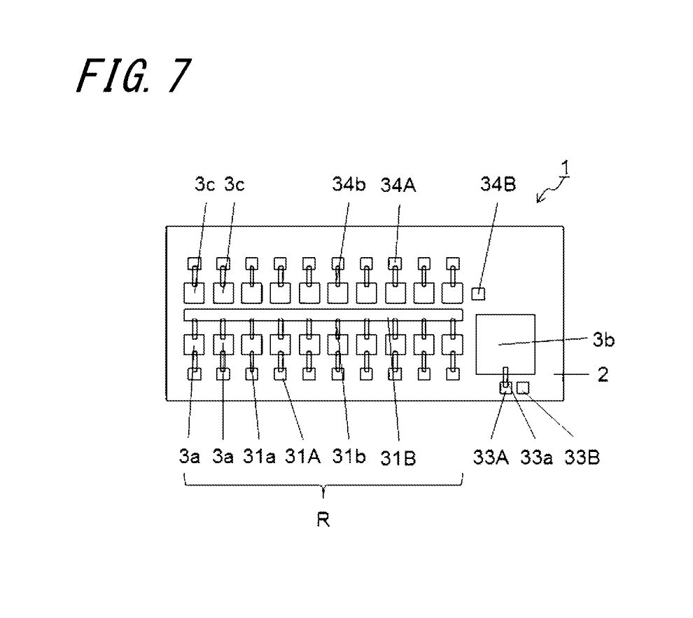

As in a fourth modification illustrated in FIG. 7, the second light receiving element may be arranged plural in the first direction along the light emitting element array R in a one-to-one relation to the plurality of light emitting elements 3a. With such an arrangement, position information of the irradiation target can be detected with high resolution.

The second light receiving elements 3c in the fourth modification are connected respectively to first electrode pads 34A on the second light receiving element side through first electrodes 34b on the second light receiving element side. A second electrode pad 34B on the second light receiving element side is further disposed and connected to the substrate 2. The second light receiving elements 3c is formed in a similar manner to the first light receiving element 3b. The first electrode 34a on the second light receiving element side is formed in a similar manner to the first electrode 33a on the first light receiving element side. The first electrode pads 34A on the second light receiving element side is formed in a similar manner to the first electrode pad 33A on the first light receiving element side. The second electrode pad 34B on the second light receiving element side is formed in a similar manner to the second electrode pad 33B on the first light receiving element side.

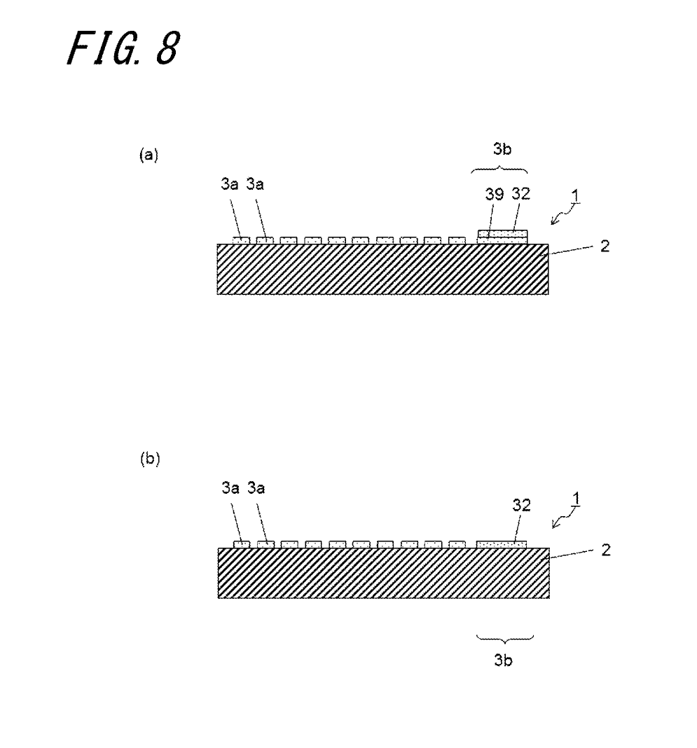

While the above embodiment has been described in connection with the case where the light emitting elements 3 are each formed by directly forming the semiconductor layers on the substrate 2, which is made of the semiconductor material, through epitaxial growth, and where the first light receiving element 3b is formed by diffusing the impurity having the opposite conductivity type into the substrate 2, the present invention is not limited to the above embodiment. Like one example of a fifth modification illustrated in FIG. 8(a), the light emitting elements 3a and the first light receiving element 3b, each formed of laminated semiconductor layers, may be both arranged on the first surface 2a of the substrate 2. In such a case, the first light receiving element 3b is constituted by a one conductivity type semiconductor region 39 and a first opposite conductivity type semiconductor region 32, which are arranged on the first surface 2a of the substrate 2. With such an arrangement, since the substrate 2 is independent of the first light receiving element 3b, various types of materials can be optionally selected as the substrate 2. For example, a sapphire substrate may be used to increase insulation performance between the elements. Alternatively, a SiC substrate or the like having a high heat dissipation effect may also be used.

Also in the above-described case, the light emitting elements 3a and the first light receiving element 3b are formed integrally with the substrate 2 without being mounted to the substrate with the aid of adhesives or pad electrodes for mounting. More specifically, the light emitting elements 3a and the first light receiving element 3b may be formed by bonding epitaxial films, which have respective desired characteristics, into the form of multilayered films on the substrate 2, and then patterning the multilayered films into the desired element shapes. Alternatively, the light emitting elements 3a and the first light receiving element 3b may be formed by forming the semiconductor layers on a substrate dedicated for crystal growth, bonding the crystal growth substrate to the substrate 2, removing the crystal growth substrate, and patterning the semiconductor layers, which are transferred to the substrate 2 from the crystal growth substrate, into the desired element shapes. The bonding of the substrate 2 and the crystal growth substrate may be performed, for example, by the normal temperature joining technique with which joining surfaces are joined to each other after activating both the surfaces at normal temperature, such that a dopant distribution will not change.

While the example illustrated in FIG. 8(a) has been described in connection with the case where the first light receiving element 3b is constituted by laminating the semiconductor layers that serve as the one conductivity type semiconductor region 39 and the first opposite conductivity type semiconductor region 32 on the first surface 2a of the substrate 2, the first light receiving element 3b may be constituted, as illustrated in FIG. 8(b), by employing, as the substrate 2, the semiconductor material having the one conductivity type, and by disposing a semiconductor layer, which constitutes the first opposite conductivity type semiconductor region 32, on the substrate 2 made of that material.

Exemplary embodiments of the sensor device 100 are not limited to the above-described exemplary embodiment.

For example, though not illustrated, the sensor device may include the light receiving/emitting element 1 according to the third modification of the present invention. With that type of sensor device, lights are sequentially applied from the plurality of light emitting elements 3a to the recording medium T as the irradiation target, and position information and distance information of the recording medium T can be detected on the basis of position information of each of the light emitting elements 3a having emitted the lights applied to the recording medium T, and output currents (photocurrents) that are output from the first light receiving element 3b and the second light receiving element 3c corresponding to the reflected lights from the recording medium T.

### Example 1

By using, as a base model, the light receiving/emitting element 1 illustrated in FIG. 1, changes in quantities of the lights received by the first light receiving element 3b were checked by simulation, as detailed below, when the distance to the irradiation target was changed. In the light receiving/emitting element 1, eight light emitting elements 3a were arrayed and successively denoted by 3a1, 3a2, . . . , 3a8 in order starting from the side closest to the first light receiving element 3b. Furthermore, the first direction was defined as an X-direction, and an XY plane parallel to a principal surface of the substrate 2 was defined by the X-direction and a Y-direction perpendicular to the X-direction. A direction normal to the XY plane was defined as a Z-direction.

First, in the light receiving/emitting element 1, relative positions of the individual light emitting elements 3a and the first light receiving element 3b were determined corresponding to distances (reference distances d1 to d8) to the irradiation target in the Z-direction, those distances being references set respectively for the individual light emitting element 3a. By employing the light receiving/emitting element 1 formed as mentioned above, the distance to the irradiation target was set to d1, and a drive current for the light emitting element 3a1 was adjusted such that the quantity of the light received by the first light receiving element 3b upon emission of the light from the light emitting element 3a1 was held at a setting value. The drive current at that time was recorded in an LED drive and control unit, not illustrated, as a drive power value specific to the light emitting element 3a1. Then, the distance to the irradiation target was set to d2, and a drive current for the light emitting element 3a2 was adjusted such that the quantity of the light received by the first light receiving element 3b upon emission of the light from the light emitting element 3a2 was held at the setting value. The drive current at that time was recorded in the LED drive and control unit, not illustrated, as a drive power value specific to the light emitting element 3a2. Subsequently, for the remaining light emitting elements 3a, respective drive power values were recorded in a similar manner to that described above. Stated in another way, the light receiving/emitting element 1 was adjusted such that the quantities of the lights received by the first light receiving element 3b were held at the same setting value for the light emitting elements 3a1 to 3a8 when the reference distances d1 to d8 were set respectively. The individual light emitting elements 3a were then driven with the above-mentioned drive current values. Simulation was performed on the quantities of the received lights and the corresponding output currents under conditions given below.

Planar shape of each light emitting element 3a: 0.2 mm square

Planar shape of the first light receiving element 3b: 1.5 mm square

Center-to-center interval between adjacent two of the plural light emitting elements 3a: 0.5 mm

Center-to-center interval L between the light emitting element 3a1 and the first light receiving element 3b: 2 mm

Incident angle θ of light emitted from the light emitting element 3a upon the irradiation target T: 45°

Reflection mode in the irradiation target T: scattering reflection is assumed to be dominant

Reference distances d1 to d8: 2 mm to 5.5 mm set at intervals of 0.5 mm

Distance D between the irradiation target T and the light emitting element 3a in the Z-direction: 2 mm to 6.5 mm set at intervals of 0.5 mm

Scan interval of the light emitting elements 3a: 1 msec (corresponding to 1 kHz)

First, for the light emitting element 3a1, the distance D was gradually increased from d1 at intervals of 0.5 mm, and change in the quantity of the received light at each distance was checked.

When the distance D is d1, the quantity of the received light is 100% as per initially set. When the distance D is set to d2, the position of the irradiation target T to which the light is applied is displaced through Δx in the X-direction toward the side where the first light receiving element 3b is positioned. Correspondingly, an incident angle (φ) of the light received by the first light receiving element 3b is also changed. Therefore, the quantity of the light received by the first light receiving element 3b attenuates in relation to a product of a field angle (cos θ) of the incident light, which depends on the incident angle θ of the light emitted from the light emitting element 3a1 and entering the irradiation target T, and a field angle (cos) at the first light receiving element 3b. Here, the term “field angle” means a visual angle of a light ray with respect to the Z-direction (normal direction) (i.e., an angle formed by the normal line and the light ray). Thus, it is found that, as listed in Table 1, the quantity of the light received by the first light receiving element 3b attenuates as the distance D increases from the reference distance d1 with the quantity of the received light at the reference distance d1 being a reference. Table 1 represents a value (I_{D}/I_{d1}) resulting from normalizing the quantity of the received light (I_{D}) at each distance by the quantity of the received light (I_{d1}) when the irradiation target T is positioned at the reference distance d1.

TABLE 1

| D (mm) | 2 | 2.5 | 3 | 3.5 | 4 | 4.5 | 5 | 5.5 | 6 | 6.5 |
|---|---|---|---|---|---|---|---|---|---|---|
| Quantity of | 1.00 | 0.96 | 0.90 | 0.84 | 0.80 | 0.76 | 0.74 | 0.71 | 0.69 | 0.68 |
| received light | | | | | | | | | | |

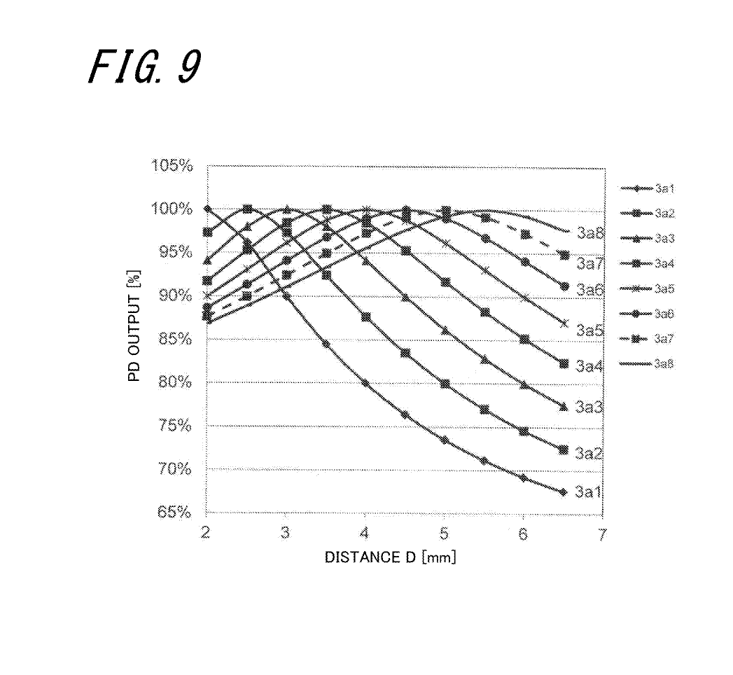

Likewise, simulations were performed on changes of the output currents from the first light receiving element 3b with respect to the lights emitted from the light emitting elements 3a1 to 3a8 when the distance D was changed from the respective reference values. FIG. 9 plots the simulation results. As seen from FIG. 9, the output currents vary depending on the changes of the distance D. The distance D can be calculated with higher accuracy and higher resolution by comparing the output currents corresponding to the plurality of light emitting elements 3a.

Furthermore, it is found that, even when the distance D exceeds the maximum reference distance d8, the measurement can be made by checking how degree the output current detected by the first light receiving element 3b attenuates from 100%. In the above simulations, the reference distances d1 to d8 are set to discrete values. However, even when the distance D takes an intermediate value different from any of the reference distances d1 to d8, the distance D can be determined by comparing the intensities of the lights emitted from the plurality of light emitting elements 3a and detected by the first light receiving element 3b.

While the plurality of light emitting elements 3a are arranged at the same interval in the embodiment described above, the intervals in the arrangement of the plurality of light emitting elements 3a may be changed such that amounts of changes in the output current from the first light receiving element 3b are held constant.

### REFERENCE SIGNS LIST

1 light receiving/emitting element
2 substrate
2a first surface
3a light emitting element
3b first light receiving element
3c second light receiving element
30a buffer layer
30b n-type contact layer
30c n-type cladding layer
30d active layer
30e p-type cladding layer
30f p-type contact layer
31A first electrode pad on light emitting element side
31B second electrode pad on light emitting element side
31a first electrode on light emitting element side
31b second electrode on light emitting element side
32, 32′ opposite conductivity type semiconductor regions (p-type semiconductor regions)
33A first electrode pad on first light receiving element side
33B second electrode pad on first light receiving element side
33a first electrode on first light receiving element side
34A first electrode pad on second light receiving element side
34B second electrode pad on second light receiving element side
34a first electrode on second light receiving element side
40 lens
100 sensor device
P1, P2 prisms
R light emitting element array

1. A light receiving/emitting element comprising a substrate, a plurality of light emitting elements on or in a first surface of the substrate, and a first light receiving element that is a photodiode in or on the first surface of the substrate,
wherein the plurality of light emitting elements are arranged in a first direction and constitute a light emitting element array,
the first light receiving element is arranged at a one end side of the light emitting element array, and
the substrate and the plurality of light emitting elements are formed integrally with each other, and the substrate and the first light receiving element are formed integrally with each other.

2. The light receiving/emitting element according to claim 1, wherein the substrate is made of a semiconductor material having one conductivity type,
the plurality of light emitting elements are each made of a plurality of semiconductor layers laminated on or in the first surface of the substrate, and
the first light receiving element includes a first opposite conductivity type semiconductor region that is formed in or on the first surface of the substrate, and that contains an impurity having an opposite conductivity type.

3. The light receiving/emitting element according to claim 2, wherein the first opposite conductivity type semiconductor region of the first light receiving element is formed by diffusing the impurity having the opposite conductivity type into the first surface of the substrate.

4. The light receiving/emitting element according to claim 1, further comprising a plurality of lenses corresponding respectively to the plurality of light emitting elements and condensing respectively lights emitted from the plurality of light emitting elements,
wherein the plurality of lenses are arranged respectively above the light emitting elements in a direction of thickness of the substrate.

5. The light receiving/emitting element according to claim 4, wherein axes of the lights emitted from the plurality of light emitting elements and applied through the plurality of lenses, respectively, are inclined toward a side where the first light receiving element is positioned.

6. The light receiving/emitting element according to claim 1, further comprising a second light receiving element that is disposed corresponding to the plurality of light emitting elements, that includes a second opposite conductivity type semiconductor regions formed in the first surface of the substrate and containing an impurity having an opposite conductivity type,
wherein the second light receiving element is arranged along the light emitting element array.

7. The light receiving/emitting element according to claim 6, wherein the second light receiving element is disposed plural in a one-to-one relation to the plurality of light emitting elements, and the plural second light receiving elements are arranged in the first direction along the light emitting element array.

8. A sensor device using the light receiving/emitting element according to claim 1,
wherein lights are sequentially applied from the plurality of light emitting elements to an irradiation target, and distance information of the irradiation target is detected on basis of position information of each of the light emitting elements having emitted the lights applied to the irradiation target, and output currents that are output from the first light receiving element corresponding to reflected lights from the irradiation target.

9. A sensor device using the light receiving/emitting element according to claim 6,
wherein lights are sequentially applied from the plurality of light emitting elements to an irradiation target, and position information and distance information of the irradiation target are detected on basis of position information of each of the light emitting elements having emitted the lights applied to the irradiation target, and output currents that are output from the first light receiving element and the second light receiving element corresponding to reflected lights from the irradiation target.

10. The light receiving/emitting element according to claim 2, further comprising a plurality of lenses corresponding respectively to the plurality of light emitting elements and condensing respectively lights emitted from the plurality of light emitting elements,
wherein the plurality of lenses are arranged respectively above the light emitting elements in a direction of thickness of the substrate.

11. The light receiving/emitting element according to claim 10, wherein axes of the lights emitted from the plurality of light emitting elements and applied through the plurality of lenses, respectively, are inclined toward a side where the first light receiving element is positioned.

12. The light receiving/emitting element according to claim 3, further comprising a plurality of lenses corresponding respectively to the plurality of light emitting elements and condensing respectively lights emitted from the plurality of light emitting elements,
wherein the plurality of lenses are arranged respectively above the light emitting elements in a direction of thickness of the substrate.

13. The light receiving/emitting element according to claim 12, wherein axes of the lights emitted from the plurality of light emitting elements and applied through the plurality of lenses, respectively, are inclined toward a side where the first light receiving element is positioned.

14. The light receiving/emitting element according to claim 2, further comprising a second light receiving element that is disposed corresponding to the plurality of light emitting elements, that includes a second opposite conductivity type semiconductor regions formed in the first surface of the substrate and containing an impurity having an opposite conductivity type,
wherein the second light receiving element is arranged along the light emitting element array.

15. The light receiving/emitting element according to claim 14, wherein the second light receiving element is disposed plural in a one-to-one relation to the plurality of light emitting elements, and the plural second light receiving elements are arranged in the first direction along the light emitting element array.

16. The light receiving/emitting element according to claim 3, further comprising a second light receiving element that is disposed corresponding to the plurality of light emitting elements, that includes a second opposite conductivity type semiconductor regions formed in the first surface of the substrate and containing an impurity having an opposite conductivity type,
wherein the second light receiving element is arranged along the light emitting element array.

17. The light receiving/emitting element according to claim 16, wherein the second light receiving element is disposed plural in a one-to-one relation to the plurality of light emitting elements, and the plural second light receiving elements are arranged in the first direction along the light emitting element array.
